(19) United States
(12) Patent Application Publication
(10) Pub. No.: US 2008/0111212 A1
(43) Pub. Date: May 15, 2008

(54) Capacitance structure of a semiconductor device and method for manufacturing the same

(75) Inventor: Hsiao-Che Wu, Jhongli City (TW)

Correspondence Address: NIXON PEABODY LLP - PATENT GROUP, 1100 CLINTON SQUARE, ROCHESTER, NY, 14604, US

(73) Assignee: Promos Technologies Inc., Hsinchu (TW)

(21) Appl. No.: 11/598,391

(22) Filed: Nov. 13, 2006

(51) Int. Cl. H01L 27/00; H01L 21/77

(52) U.S. Cl. 257/532; 438/396; 257/E27.001; 257/E21.598

(57) ABSTRACT

A capacitance structure of a semiconductor device and a method for manufacturing the structure are provided. The capacitance structure comprises a plurality of capacitance elements and a plurality of supports. Each of the capacitance elements has a column, and each of the supports is disposed between two adjacent columns by partially connecting onto the outer surface of each of the two adjacent columns. Thereby, the mechanical properties of the capacitance structure can be enhanced.

### CROSS-REFERENCES TO RELATED APPLICATIONS

Not applicable.

### BACKGROUND OF THE INVENTION

1. Field of the Invention

The present invention relates to a capacitance structure of a semiconductor device and a method for manufacturing the same. In particular, the invention relates to a capacitance structure with support elements and a method for manufacturing the same.

2. Descriptions of the Related Art

A DRAM (Dynamic Random Access Memory) is composed of a plurality of memory cells which are ranged into an array. In general, each of the memory cells comprises a capacitance structure and a MOSFET (Metal Oxide Semiconductor Field Effect Transistor), wherein the MOSEFT controls the electricity charge-discharge and the read-out and the source electrode of the MOSFET is electrically connected to the electrode of the capacitance structure.

Further, conventional capacitance structures of DRAM can be categorized into two groups: stack type and trench type. The capacitance structure in stack type is directly formed onto the surface of the silicon substrate, while the capacitance structure in trench type is formed within the silicon substrate.

However, as manufacturing techniques progress and as final products are minimized, the integration of a DRAM has also increased. Accordingly, the size of a DRAM with the same capacitance structure tends to be smaller, and this causes the reduction of the effective surface area of a capacitance structure. In other words, the effective capacitance will decrease. As a result, the performance of the DRAM is negatively affected.

To enhance the effective capacitance of a capacitance structure while minimizing the size of the DRAM, the aspect ratio of the capacitance structure could be increased. This can be achieved by increasing the longitudinal surface of the capacitance structure, or alternatively forming the capacitance structure into a hollow cylinder configuration. However, the capacitance structure with the hollow cylinder configuration has poor mechanical properties. The chances of tilting, breaking or even collapsing the structure is increased, and ultimately leads to lower yields.

Thus, the present invention solves the aforementioned problems. That is, a capacitance structure with a hollow cylinder configuration and proper support elements is provided. In addition, a method for manufacturing the structure is also provided.

### SUMMARY OF THE INVENTION

The primary objective of this invention is to provide a capacitance structure of a semiconductor device with a hollow cylinder configuration and a method for manufacturing the structure. A plurality of supports is independently formed between adjacent capacitance structures to significantly enhance the mechanical properties thereof. These supports can also prevent the structure from tilting or breaking when it has a high aspect ratio.

Another objective of this invention is to provide a capacitance structure of a semiconductor device with a hollow cylinder configuration and a method for manufacturing the structure. In the manufacturing process, a bottom electrode is formed and then the supports disposed between the adjacent capacitance structures are subsequently formed. Thus, independent supporting structures can be formed without altering the original manufacturing processes.

To achieve the aforementioned objectives, the present invention provides a capacitance structure of a semiconductor device. The capacitance structure comprises a plurality of capacitance elements and a plurality of supports. Each of the capacitance elements includes a column, and each of the supports is disposed between two adjacent columns by partially connecting onto the outer surface of each of the two adjacent columns.

The present invention further provides a method for manufacturing the aforesaid structure. The method comprises the following steps: (a) forming a plurality of solid columns in a stack structure in which the stack structure has an upper surface that is lower than the upper end of the solid column and the outer wall together with the bottom of each solid column form a first electrode; (b) forming a support between two adjacent solid columns in which the support partially connects onto the outer wall of the solid column; (c) removing the interior of each solid column, while leaving the first electrode; (d) forming a dielectric layer on the first electrode; and finally, (e) forming a second electrode on the dielectric layer.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIGS. 1, 1A, and 1B are schematic views of forming a stack structure;

FIGS. 2, 2A, and 2B are schematic views of forming trenches on the stack structure;

FIGS. 3, 3A, and 3B are schematic views of forming lower electrodes;

FIGS. 4, 4A, and 4B are schematic views of an etching process of the present invention;

FIGS. 5, 5A, and 5B are schematic views of the first step of forming supports;

FIGS. 6, 6A, and 6B are schematic views of the second step of forming supports;

FIGS. 7, 7A, and 7B are schematic views of the third step of forming supports;

FIGS. 8, 8A, and 8B are schematic views of removing the first and second silicon oxide layers;

FIGS. 9A, and 9B are schematic views of forming the upper electrodes of the capacitance structure; and

FIGS. 10A, and 10B are schematic views of an embodiment of the capacitance structure of the present invention.

### DESCRIPTION OF THE PREFERRED EMBODIMENT

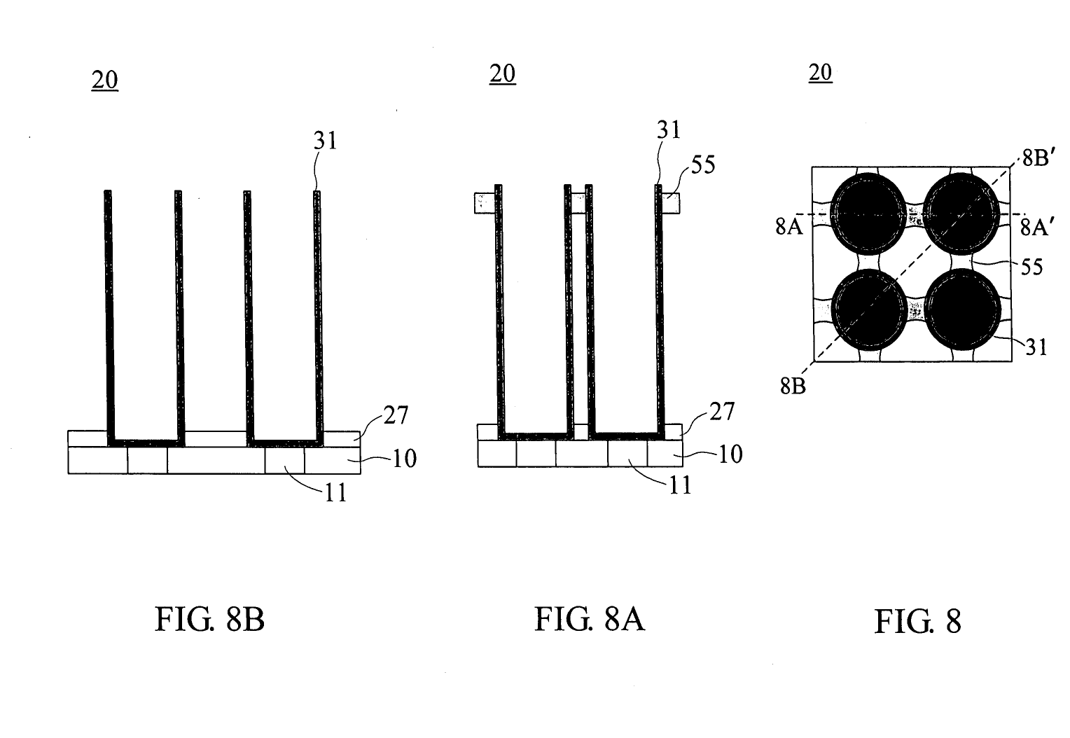

A capacitance structure 20 of the present invention is shown in FIGS. 8 to 10B in which FIG. 8A is a cross-sectional view of the capacitance structure 20 along the line 8A-8A′ of FIG. 8. FIG. 8B is a cross-sectional view along the line 8B-8B′. The capacitance structure 20 of the present invention is formed on a substrate 10 and comprises a plurality of capacitance elements 30 and a plurality of supports 55. Each of the capacitance elements 30 has a column 40 and each of the supports 55 is independently disposed between two adjacent columns 40 and partially connected to the outer surface of the column 40. The column 40 is a substantially hollow column, preferably, a hollow cylinder, and has an open end 41. The support 55 is disposed adjacent to the open end 41 of the column 40 to provide effective support.

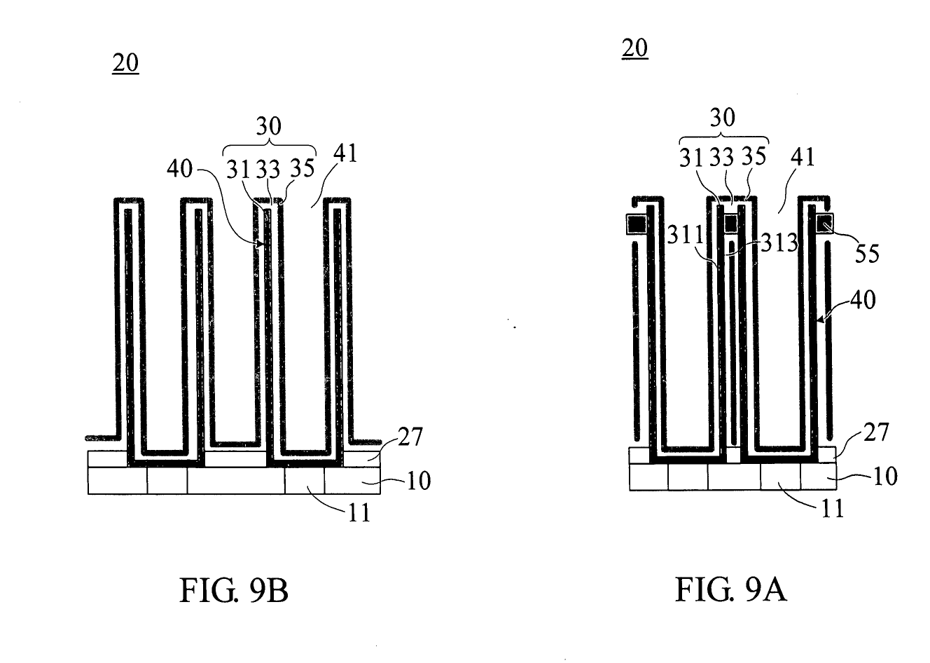

Specifically, as shown in FIGS. 9A and 9B, the abovementioned capacitance element 30, from the outer surface to the interior, successively comprises a first electrode 31, a dielectric layer 33, and a second electrode 35. The first electrode 31 has an inner wall 311 and an outer wall 313, in which the outer wall 313 forms the outer surface of the column 40. The dielectric layer 33 at least covers the inner wall 311 of the first electrode 31. In this embodiment, the dielectric layer 33 covers the inner wall 311 and the outer wall 313 of the first electrode 31. The second electrode 35 covers the dielectric layer 33.

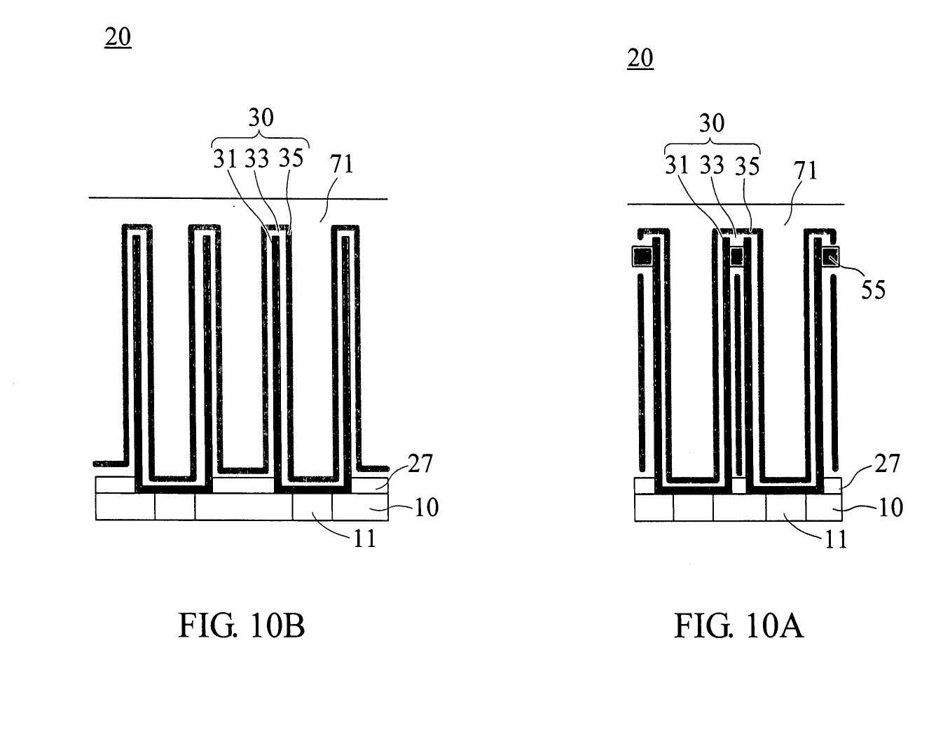

With reference to FIGS. 10A and 10B, the capacitance structure 20 of the present invention can further comprise an oxide layer 71 which covers the second electrode 35.

It is noted that the support 55 is preferably made from Al₂O₃ or silicon nitride, while the dielectric layer 33 is made from Al₂O₃, hafnium dioxide (HfO₂), titanium dioxide (TiO₂), zirconium dioxide (ZrO₂), barium titanate, strontium titanate, or barium-strontium titanate.

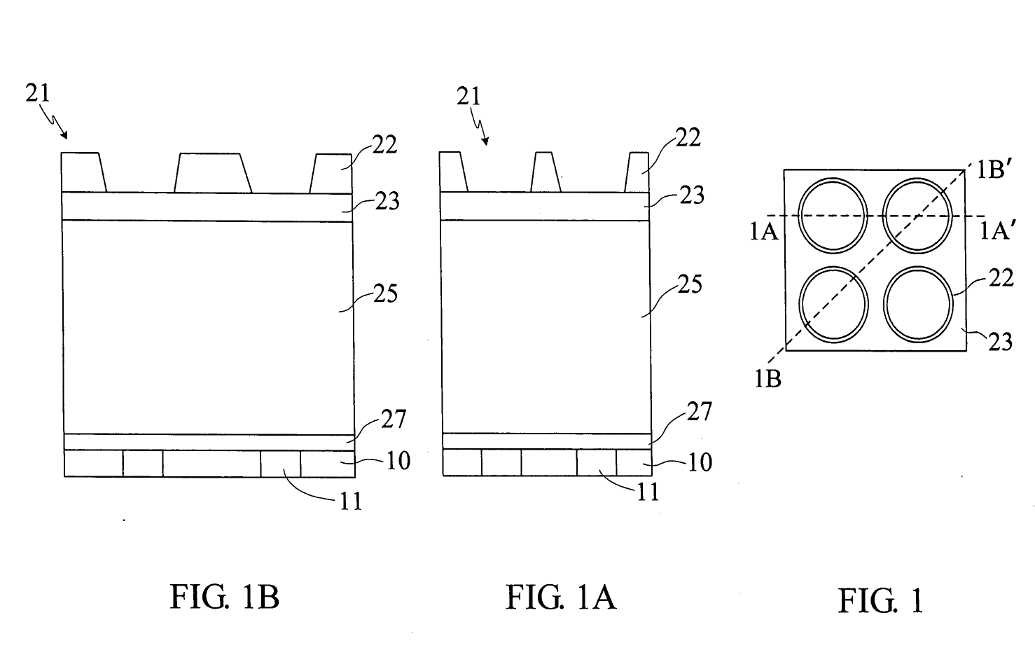

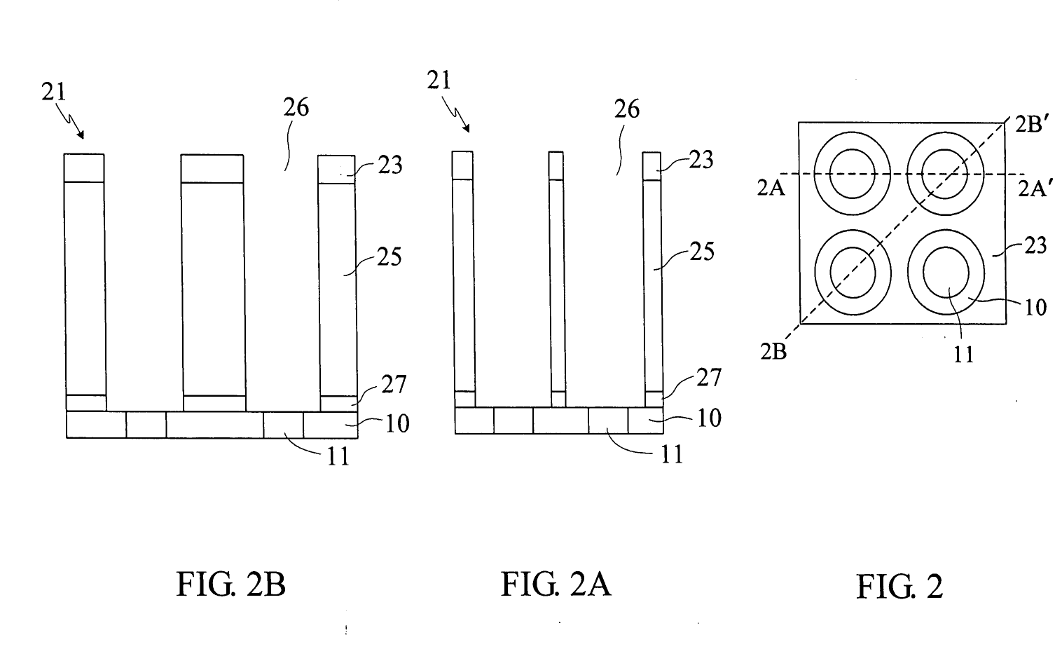

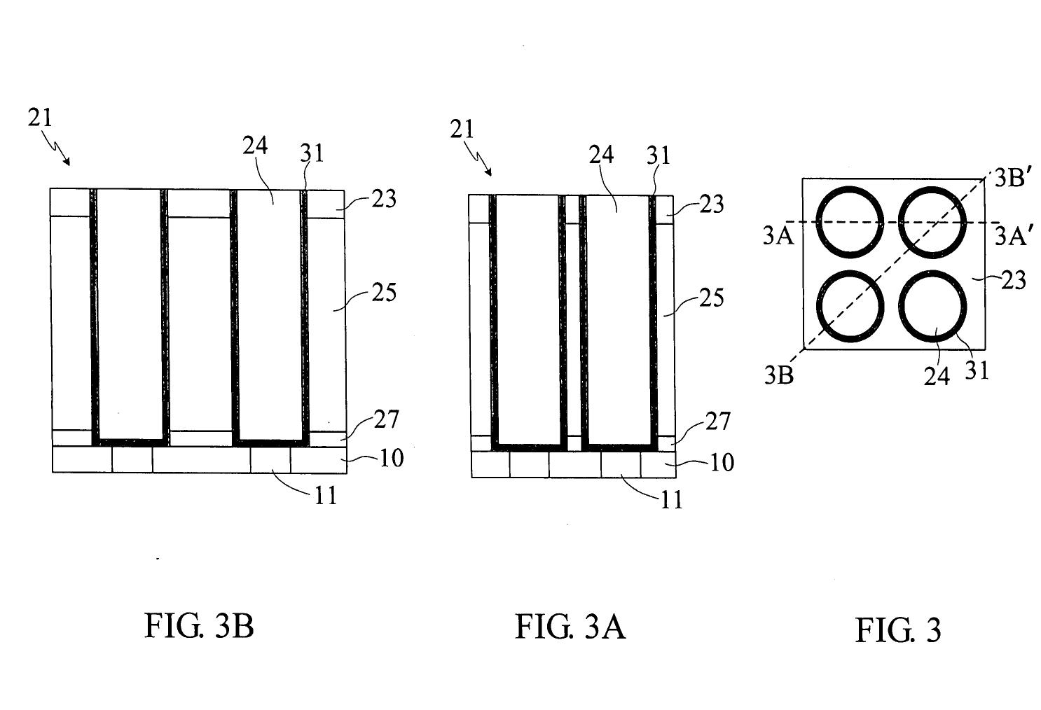

The present invention also provides a method for manufacturing the capacitance structure 20. First, with reference to FIGS. 1, 1A, and 1B, a stack structure 21 is formed on the substrate 10. As shown in FIGS. 2, 2A, and 2B, a plurality of trenches 26 with column configurations, preferably cylinders, are formed on the stack structure 21. Then, the first electrode 31 is deposited along the interior of the trench 26. On the first electrode 31, a dielectric layer (e.g. a first silicon oxide layer 24) is deposited to form solid columns as shown in FIGS. 3, 3A, and 3B.

More specifically, in an embodiment, the stack structure 21 comprises a first silicon nitride layer 23, a dielectric layer (e.g. a second silicon oxide layer 25), and a second silicon nitride layer 27 from top to bottom. The second silicon nitride layer 27, the second silicon oxide layer 25, and the first silicon nitride layer 23 are successively deposited onto the substrate 10 so that the first silicon nitride layer 23 is located on the top of the stack structure 21. Thereafter, a patterned mask layer 22 is formed onto the first silicon nitride layer 23 for the following etching process.

As shown in FIGS. 2, 2A, and 2B, a plurality of trenches 26 with column configurations are formed by etching. In this process, the first silicon nitride layer 23 and the second silicon oxide layer 25 are partially removed by etching according to the pattern of the mask layer 22. Then, the mask layer 22 is removed for partially etching the second silicon nitride layer 27. In this step, the substrate 10 is partially exposed for connection with a source electrode 11 of the transistor.

As shown in FIGS. 3, 3A, and 3B, the first electrode 31 is deposited on the interior surface of the trenches 26. On the first electrode 31, the first silicon oxide layer 24 is deposited to form the abovementioned solid column. Preferably, a CMP (chemical mechanical polishing) process is carried out to flatten the surface.

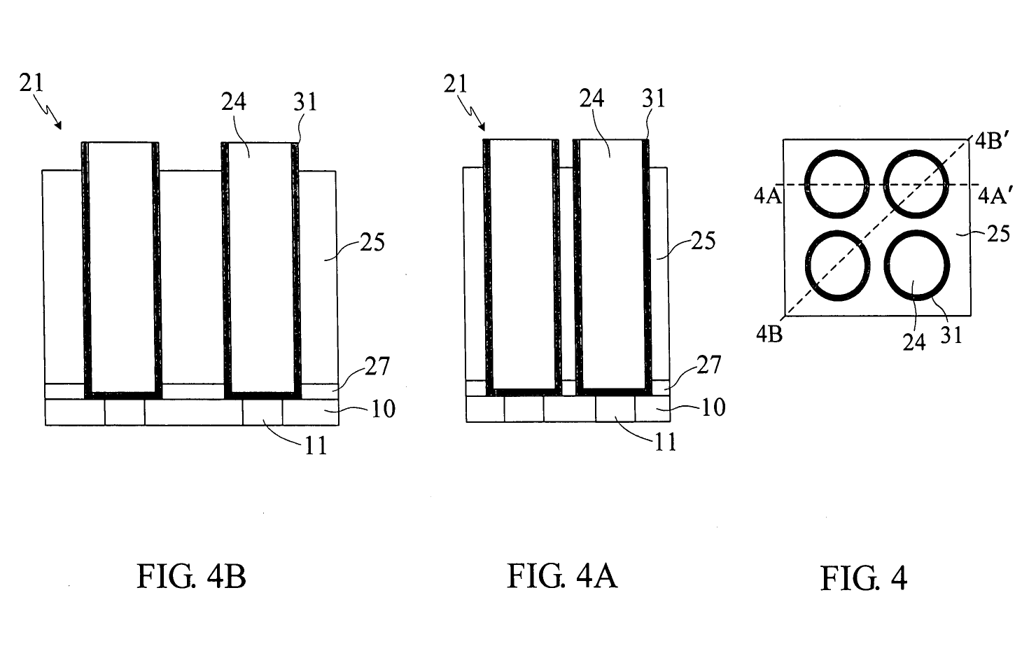

With reference to FIGS. 4, 4A, and 4B, the first silicon nitride layer 23 is then removed, preferably, by using phosphoric acid (H₃PO₄). Thus, a plurality of solid columns are formed in the stack structure 21. More specifically, as a result of the removal of the first silicon nitride layer 23 from the stack structure 21, the upper end of the solid column is higher than the upper surface of the stack structure 21. In addition, the outer wall and the bottom of each the solid columns form the first electrode 31.

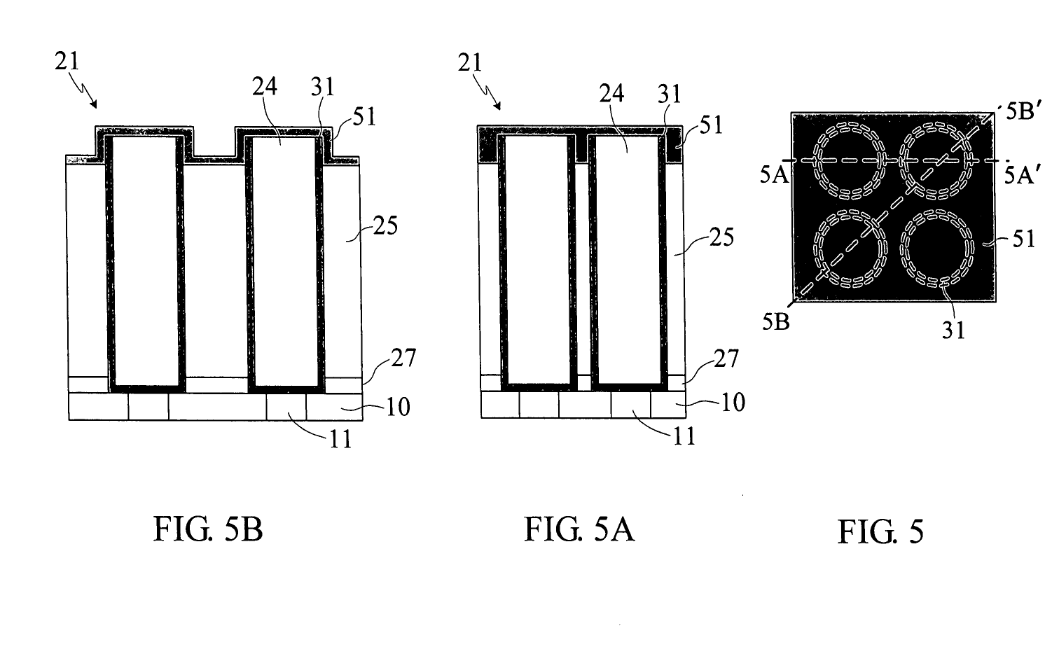

Thereafter, the following steps are conducted to form the supports. With reference to FIGS. 5, 5A, and 5B, a third silicon nitride layer 51 is formed onto both the stack structure 21 and the solid columns. This can be done by an LPCVD (low pressure chemical vapor deposition) process, for example. Alternatively, the layer 51 can also be made from Al₂O₃ which is not limited herein.

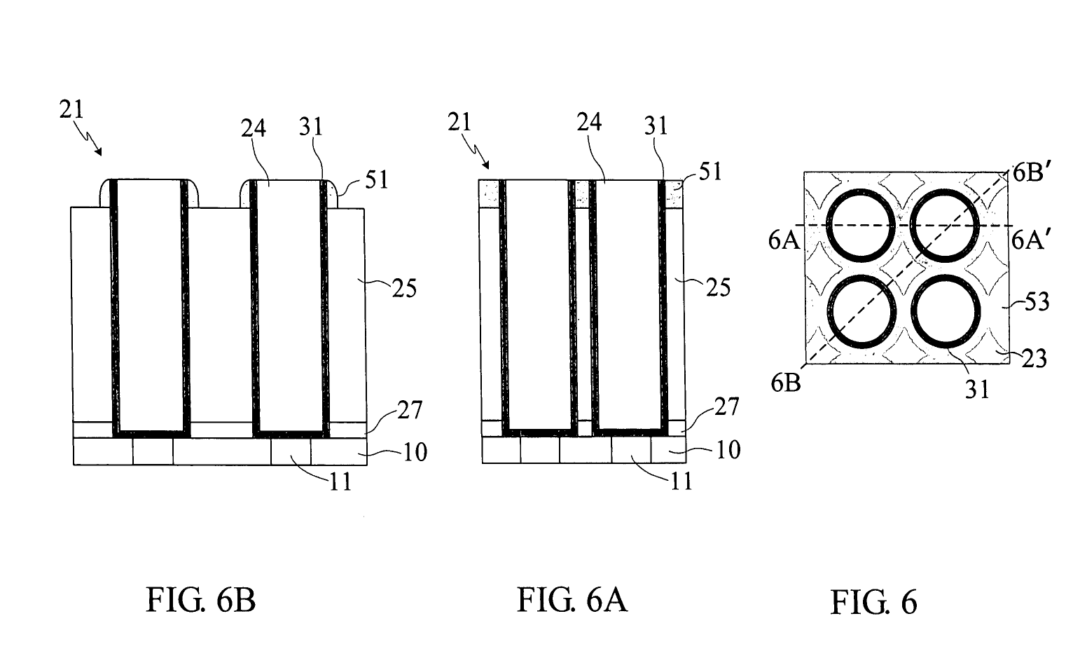

Continuing with reference to FIGS. 6, 6A, and 6B, the third silicon nitride layer 51 is partially removed by performing an anisotropic etching process. More specifically, the anisotropic etching process partially removes the third silicon nitride layer 51, which is located above the first silicon oxide layer 24 of the solid columns or above the second silicon oxide layer 25 of the stack structure 21, and leaves behind the third silicon nitride layer 51 surrounding the outer wall of the solid column as shown in FIG. 6. For forming the third silicon nitride layer 51 with an annular configuration, the thickness t of the third silicon nitride layer 51, which is left after etching, should be noticed. In general, if the interval between the solid columns is defined as d, the thickness t should meet the condition of t>0.5 d so that the annular structure can mutually connect therewith. Preferably, the thickness t meets the condition of t≧0.7 d, and more preferably, t=d.

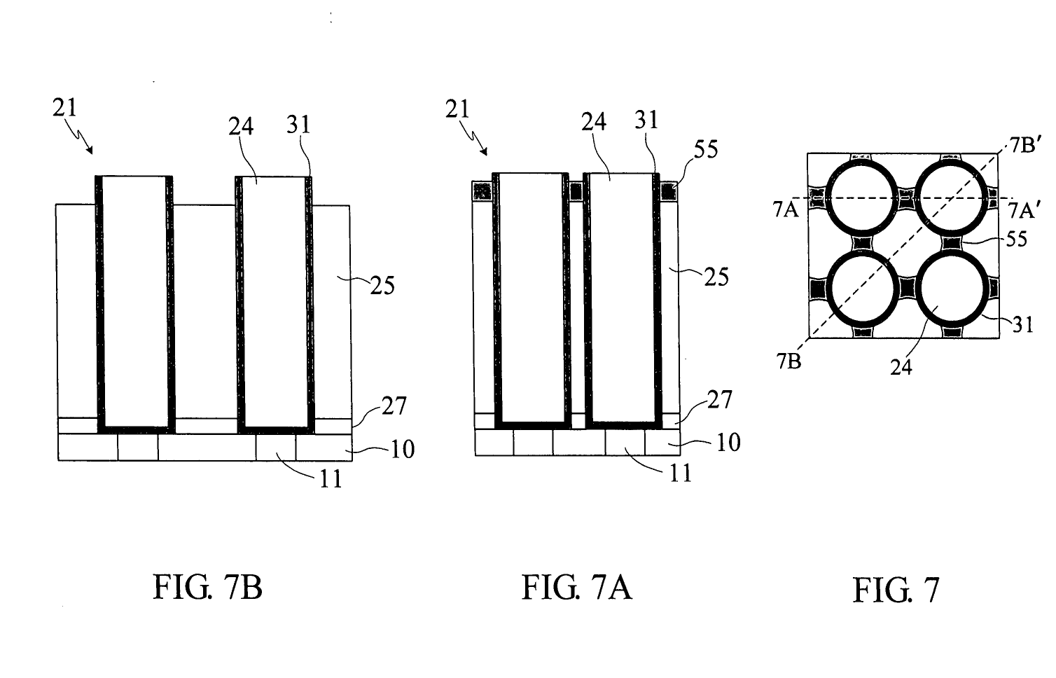

Next, as shown in FIGS. 7, 7A, and 7B, an isotropic etching process is performed. In this respect, a “pull back” process is carried out on the third silicon nitride layer 51 by wet etching. After that, the third silicon nitride layer 51 is partially removed and thus a plurality of supports 55 is left behind. In other words, the third silicon nitride layer 51 turns from a layer structure into a plurality of supports 55. These supports 55 are independently located between adjacent solid columns and partially connected onto the outer wall of the solid columns.

With reference to FIGS. 8, 8A, and 8B, the interior and the exterior dielectric layers (i.e. the aforementioned first silicon oxide layer 24 and second silicon oxide layer 25) of each solid column are removed to leave the first electrode 31 behind for forming the capacitance element 30. First, as shown in FIGS. 9A and 9B, the dielectric layer 33 is formed onto the first electrode 31. Specifically, an ALD (atomic layer deposition) process can be used to form the dielectric layer 33 that covers the inner wall 311 and the outer wall 313 of the first electrode 31. The second electrode 35 is then deposited onto the dielectric layer 33. Finally, the oxide layer 71 is deposited onto the second electrode 35 as shown in FIGS. 10A and 10B.

With the above-disclosed structure, the supports 55 are independently disposed between the adjacent capacitance elements 30 in the capacitance structure 20 of the present invention. Therefore, the mechanical properties of the whole capacitance structure 20 can be enhanced. In addition, when the aspect ratio is increased, the possibility of tilting or breaking the structure is decreased.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A capacitance structure of a semiconductor device, comprising:
a plurality of capacitance elements, wherein each of the capacitance elements includes a column having an outer surface; and
a plurality of supports, wherein each of the supports is independently disposed between the two adjacent columns and partially connecting onto the outer surface of each of the two adjacent columns.

2. The capacitance structure of claim 1, wherein the column substantially is a hollow cylinder and has an open end.

3. The capacitance structure of claim 2, wherein the supports are disposed adjacent to the open ends of the columns.

4. The capacitance structure of claim 1, wherein the capacitance element, from the outer surface to the interior, successively comprises:
a first electrode, having an inner wall and an outer wall, in which the outer wall forms the outer surface of the column;
a dielectric layer, covering on the inner wall of the first electrode; and
a second electrode, covering on the dielectric layer.

5. The capacitance structure of claim 4, wherein the dielectric layer covers the inner wall and the outer wall of the first electrode.

6. The capacitance structure of claim 5, further comprising an oxide layer deposited on the second electrode.

7. The capacitance structure of claim 1, wherein the supports are made from Al₂O₃ or silicon nitride.

8. The capacitance structure of claim 4, wherein the dielectric layer is made from Al₂O₃, hafnium dioxide (HfO₂), titanium dioxide (TiO₂), zirconium dioxide (ZrO₂), barium titanate, strontium titanate, or barium-strontium titanate.

9. A method for manufacturing a capacitance structure of a semiconductor device, comprising the following steps:
(a) forming a plurality of solid columns in a stack structure, wherein the stack structure has an upper surface, an upper end of the solid column is higher than the upper surface of the stack structure, and a first electrode is constructed by an outer wall and a bottom of each the solid column;
(b) forming a support between the two adjacent solid columns, and the support partially connecting onto the outer wall of each of the two adjacent solid columns;
(c) removing an interior of each the solid columns and leaving the first electrode behind;
(d) forming a dielectric layer on the first electrode; and
(e) forming a second electrode on the dielectric layer.

10. The method of claim 9, wherein the step (a) comprises the following steps:
(a-1) forming the stack structure, which comprises a first silicon nitride layer on the top;
(a-2) forming a plurality of trenches on the stack structure, in which the trenches are substantially cylindrical;
(a-3) depositing the first electrode in the trenches;
(a-4) depositing a first silicon oxide layer on the first electrode to form the solid columns; and
(a-5) removing the first silicon nitride layer.

11. The method of claim 10, wherein the stack structure further successively comprises a second silicon oxide layer and a second silicon nitride layer under the first silicon nitride layer.

12. The method of claim 11, wherein the step (c) is to remove the first silicon oxide layer in each the solid column and the second silicon oxide layer out of each the solid column.

13. The method of claim 10, wherein the step (a-2) comprises:
forming a mask layer with a pattern on the first silicon nitride layer previously, serving as a mask for forming the plurality of trenches in an etching process.

14. The method of claim 13, wherein the etching process comprises the following steps:
etching the first silicon nitride layer, etching the second silicon oxide layer, removing the mask layer, and etching the second silicon nitride layer.

15. The method of claim 10, wherein the step (a-5) is removing the first silicon nitride layer by using phosphoric acid (H₃PO₄).

16. The method of claim 9, wherein the step (b) comprises the following steps:
(b-1) forming a third silicon nitride layer on the stack structure and the solid columns by performing an LPCVD (Low Pressure Chemical Vapor Deposition) process.
(b-2) partially removing the third silicon nitride layer which is above the solid columns by performing an anisotropic etching process; and
(b-3) partially removing the left third silicon nitride layer by performing an isotropic etching process to leave only the third silicon nitride between the adjacent solid columns.

17. The method of claim 9, wherein the step (d) is forming the dielectric layer on the first electrode by performing an ALD (Atomic Layer Deposition) process.

18. The method of claim 9, wherein the step (c) is depositing the second electrode on the dielectric layer.

19. The method of claim 9, further comprises a step (f) depositing an oxide layer on the second electrode.
